(19) United States
(12) Patent Application Publication
(10) Pub. No.: US 2021/0124077 A1
(43) Pub. Date: Apr. 29, 2021

(54) LIVING BODY DETECTION METHOD AND APPARATUS (TOUCHING BEHAVIOR)

(71) Applicant: Vicwood Prosperity Technology Limited, Hong Kong (HK)

(72) Inventors: Man Yau Law, Hong Kong (HK); Hin Hung Ng, Hong Kong (HK)

(21) Appl. No.: 17/054,172

(22) PCT Filed: May 10, 2019
(86) PCT No.: PCT/IB2019/053862

§ 371 Date: Nov. 10, 2020

(30) Foreign Application Priority Data
May 11, 2018 (HK) 18106178.1

(51) Int. Cl. G01V 3/08; G01V 3/02

(52) U.S. Cl. CPC G01V 3/088; G01V 3/02

(57) ABSTRACT

A method of detecting possible living body contact at an electrical conductive surface, wherein the living body has a contact portion having electrical properties resembling an impedance bridge comprising a plurality of resistors and a plurality of capacitors connected in series and parallel and having a characteristic rise-time and a characteristic fall-time, wherein the impedance bridge comprises a resistor series (R₀+R₁+R₂) having a total resistance value and a resistor-capacitor first RC bridge comprising a parallel connection of a first resistor (C₁) having a first resistance value and a first capacitor (R₁) having a first capacitance value, and the resistor series (R₀+R₁+R₂) comprises an internal resistor (R₀) in series connection with the first RC bridge and having an internal resistance value.

### FIELD

The present disclosure relates to methods and apparatus for detecting living body contact at a contact surface, and to methods and apparatus for controlling power supply to mitigate risks of electrical shock.

### BACKGROUND

Electricity is a form of energy that is present almost everywhere in modern livings. However, the human body and other living bodies are somewhat conductive and electrical current passing through a human body can cause electric shock and be fatal.

Studies have shown that different parts of the human body can be regarded as forming a circuit comprising distributed resistive (R) and capacitive (C) components, and the values of impedances of the resistive (R) and capacitive (C) components depend on a number of factors such as the current path, the touch voltage, the duration of current flow, the current frequency, the degree of moisture of the skin, the surface area of contact, the pressure exerted and the temperature. From arm-to-arm or arm-to-leg, the resistance is typically between 1 kΩ to 1 MΩ, but the resistance can drop to 100Ω with punctured skin.

Below are some typical threshold values when a current of 15-100 Hz passes through a human body:

| | |
|---|---|
| 1 mA | Threshold of perception |
| 5 mA | Noticeable shock, involuntary movement |
| 10 mA | Let-go threshold |
| 30 mA | Possible ventricular fibrillation |
| 50 mA | Probable ventricular fibrillation |
| 100 mA | Respiratory arrest, fibrillation, death becoming likely |
| 1 A | Nerve damage, burns, death likely |

Ventricular fibrillation is known to be the main cause of fatal electric shock accidents in the frequency range of 15 Hz to 100 Hz, and 50 Hz and 60 Hz are of course the standard mains supply frequency.

It is desirable to provide means or measures to mitigate risks of fatal electrical shocks.

### DISCLOSURE

Electric currents are essential for operations of vital human organs such as the heart and the brain. However, an electric current having an amplitude of current and a flow duration exceeding a safe limit can be hazardous and can cause injuries or death by electrocution.

A living person can feel an electric current if the current flowing through the person reaches a magnitude known as a threshold of perception. The threshold of perception depends on several parameters, such as the area of body contact (“contact area”), the conditions of contact (dry, wet, pressure, temperature), and also on physiological characteristics of the individual. The threshold of perception for an AC (alternating current) current of 50/60 Hz is typically between 0.25 mA to 1 mA. The DC (direct current) threshold of perception is about four times the AC threshold of perception.

Electric current can cause a person to lose muscular control if the current flowing through the person reaches a magnitude known as a “let-go” threshold. When this happens, the person would not be able to control his/her muscle to move away from an electrified contract surface until the currents flow stops. The let-go threshold depends on several parameters, such as the contact area, the shape and size of the electrodes and also on the physiological characteristics of the person. The let-go threshold for an AC (alternating current) current of 50/60 Hz is typically taken as about 10 mA and there is no definable let-go threshold for DC.

Electric current can cause ventricular fibrillation if the current flowing through the person reaches a magnitude known as a threshold of ventricular fibrillation. Ventricular fibrillation is considered to be the main cause of death by electrical shock, although there is also some evidence of death due to asphyxia or cardiac arrest. The threshold of ventricular fibrillation depends on physiological parameters, such as anatomy of the body, state of cardiac function, etc., as well as on electrical parameters, such as duration and pathway of current flow, current parameters, etc. For shock durations by AC currents below 100 millisecond (ms), ventricular fibrillation may occur at a current magnitude above 500 mA. For shock durations longer than the cardiac cycle, the threshold of fibrillation for DC is several times higher than for AC. For shock durations shorter than 200 ms, the threshold of fibrillation is approximately the same as for AC measured in root-mean-square (rms) values.

The human body permits flow of electric current and can be considered as a passive network comprising resistive and capacitive components in so far as studies of electrical shock are concerned.

The human body can be regarded as a passive impedance network comprising a first skin impedance (Zₚ₁), a second skin impedance (Zₚ₂) and an internal impedance (Zᵢ) for studies of electrical safety. The first skin impedance (Zₚ₁), the second skin impedance (Zₚ₂) and the internal impedance (Zᵢ) are electrically connected in series, with the internal impedance electrically (Zᵢ) interconnecting and intermediate the first and second skin impedances. The total impedance (Z_{T}) of the human body is equal to Zₚ₁+Zᵢ+Zₚ₂, wherein Zₚ₁, Zᵢ and Zₚ₂ correlate to Z₁, Z₀ and Z₂ respectively in FIG. 3B.

The internal impedance of the human body has impedance characteristics of a parallel connection of a resistive component and a capacitive component, and can be represented by an equivalent circuit of an impedance network comprising an internal resistor Rᵢ and an RC (resistor and capacitor) branch connected in parallel. The RC branch consists of a second internal resistor and an internal capacitor Cᵢ connected in series (Source: British standard document PD6519-1:1995, FIG. 1). The value of the internal impedance (Zᵢ) depends primarily on the current path and, to a lesser extent, on the surface area of the contact. Experiments show that the internal capacitance Cᵢ has a value of several picofarad (pF).

The skin impedance of the human body has impedance characteristics of a parallel connection of a resistive component and a capacitive component, and can be represented by an equivalent circuit of an impedance network comprising a resistor having a skin resistance Rₚᵢ and a capacitor having a skin capacitance Cₚᵢ connected in parallel, where i=1 or 2. Studies show that the skin resistance Rₚᵢ has a value of several hundred kohm (kΩ) (Source: British standard document PD6519-1:1995).

The value of the skin impedance (Zₚ₁, Zₚ₂) depends on the voltage, frequency, duration of the current flow, surface area of contact, pressure of contact, the degree of moisture of the skin, temperature and type of the skin. For touch voltages up to approximately 50 V AC, the value of the impedance of the skin of a person varies widely with surface area of contact, temperature, perspiration, rapid respiration, and other factors. For higher touch voltages over approximately 50 V, the skin impedance decreases considerably and becomes negligible when the skin breaks down. The skin impedance falls when the current is increased (Source: British standard document PD6519-1:1995)

A living human body appears to have the electrical properties and characteristics of a passive impedance network which is resistive and capacitive and can be represented as such a network in so far as electrical shock safety studies and solutions are concerned. However, the values of the various resistive and capacitive elements forming the network appear to be non-constant and non-linear and vary widely according to many factors and parameters, such as contact area, current path(s), conditions of contact (dry, wet, pressure, temperature) and physiological parameters of the living body and characterization of the human bodies without complicated algorithms is difficult, if not impossible. However, it is found that the impedances of human bodies are within a predictable range.

For example, the values of total body impedance Z_{T} with a hand to hand current path and large contact area (5,000 square mm (mm²) to 10,000 square mm) for an example touch voltage of 10V and example frequencies from 25 Hz to 20 kHz and measured using 10 living human body samples fall from a maximum impedance at the low frequency end to a minimum impedance at the high frequency end. The maximum impedance at the low frequency end (25 Hz in the example) has an average value of about 5.3 kΩ or 5.4 kΩ and a variation of about 3 kΩ, or about 1.5 kΩ on both sides of the average. The minimum impedance at the high frequency end (20 kHz in the example) was found to have an average value of about 900Ω and a variation of about 80Ω-100Ω, or 40Ω-50Ω on both sides of the average. The total body impedance Z_{T} decreases rapidly from the maximum impedance value at the low frequency end to stabilize asymptotically at about 5 kHz to 10 kHz. The change in total body impedance Z_{T} at 10 kHz or above is found to be small and in the 40Ω-50Ω range (Source: British standard document PD6519-1:1995, FIG. 6).

For example, the values of total body impedance Z_{T} with a hand to hand current path and large contact areas (5,000 square mm (mm²) to 10,000 square mm) for an example touch voltage of 25V and example frequencies from 25 Hz to 2 kHz and measured using 10 living human body samples fall from a maximum impedance at the low frequency end to a minimum impedance at the high frequency end. The maximum impedance at the low frequency end (25 Hz in the example) has an average value of about 3.23 kΩ or 3.3 kΩ. The minimum impedance at the high frequency end (2 kHz in the example) was found to have an average value of about 7000. The total body impedance Z_{T} decreases rapidly from a maximum impedance value at the low frequency end to stabilize asymptotically at about 2 kHz (Source: British standard document PD6519-1:1995, FIG. 7).

For example, the total body impedance of a population for a percentile rank of 50% for touch voltages from 10V to 1000V AC and a frequency range from 50 Hz to 2 kHz for a current path hand to hand or hand to foot varies between about 5.5 kΩ at 10V AC 50 Hz and about 1.1 kΩ at 1 kV AC 50 Hz. The total body impedance for touch voltages at or above 50V AC all converge to approach an asymptotic value of about 6500 at about 2 kHz (Source: British standard document PD6519-1:1995, FIG. 8).

For example, the values of total body impedance Z_{T} with a hand to hand current path at AC 50/60 Hz for large contact areas at 25V is between 17500 (5% of population) and 6100Ω (95% of population), with 50% of population at 3250Ω; at 50V is between 14500 (5% of population) and 4375Ω (95% of population), with 50% of population at 2625Ω; at 75V is between 12500 (5% of population) and 2200Ω (95% of population), with 50% of population at 2200Ω; and at 100V is between 12000 (5% of population) and 3500Ω (95% of population), with 50% of population at 1875Ω (Source: British standard document PD6519-1:1995, Table 1).

When a living person touches a contact surface which has a surface voltage so that there is a voltage difference or a potential difference between the living person and the contact surface, a current will flow through the body of the living person (“living body” in short). For example, when a living person touches a contact surface which is at an elevated voltage or a positive voltage above the voltage of the living body, a current will from the contact surface into the living body due to the voltage difference or potential difference between the living body and the conduct surface. Conversely, when a living person touches a contact surface which is at a depressed voltage or a negative voltage below the voltage of the living body, a current will flow from the living body into the contact surface. While the descriptions herein are with reference to a contact surface having an elevated voltage with respect to a living body, it should be understood that the descriptions, terms and features shall apply mutatis mutandis to the condition where the contact surface is at a depressed voltage with respect to the voltage of aliving body without loss of generality. A contact surface herein means an electrical conductive contact surface which permits flow of electrical current and a current herein means electrical current without loss of generality.

Experiments and measurements show that when aliving body touches a contact surface which is at a constant voltage or a DC voltage elevated above the voltage of the living body, there is an inrush of current (or “current inrush” in short) that flows into the living body at the instant or moment when the living body is in direct electrical contact with the contact surface. The current inrush occurs almost immediately or instantaneously in response to the contact surface touching and the current that flows into the living body follows a substantially regular pattern of rising to a current peak within a very short rise-time and then falls from the current peak to a steady state current level after a fall time which is substantially longer than the rise-time. The aforesaid substantially regular pattern that the responsive current rising to a current peak within a very short rise-time and then falls from the current peak to a steady state current level after a fall time which is substantially longer than the rise-time is repeatable and is believed to represent a characteristic electrical response profile of aliving body when touching a contact surface which is at an elevated constant voltage or a DC voltage. The inrush current is in the form of an asymmetrical current pulse having a current magnitude profile which is non-symmetrical about the current peak in the time domain, with the current peak at or very close to the time domain origin, that is, the time domain zero.

Experiments and measurements show that it is possible to determine whether there is living body contact at a contact surface by sending a non-hazardous probing signal to the contact surface and evaluating responsive signals coming from the contact surface in response to the probing signal. In devising a suitable probing signal, it is noted that the touching of a contact surface which is at an elevated voltage level by a living person is effectively equivalent to the application of a step voltage pulse having a voltage amplitude equal to the elevated voltage level as a touch voltage to the human body.

A method of detecting possible living body contact at an electrical contact surface is disclosed. The living body has a detectable characteristic initial impedance and a corresponding characteristic time constant defined by the initial impedance upon touching the electrical contact surface when the electrical contact surface is at a touching voltage.

A method of detecting possible living body contact at a contact surface which is an electrically conductive surface is disclosed. The method may comprise a controller: operating a probing circuit to generate a train of probing signals to the contact surface, the train of probing signals may comprise a plurality of probing pulses and each probing pulse has a probing voltage and a probing-pulse duration; operating a detection circuit to detect current responses and collect current response parameters from the contact surface, the current response parameters being current parameters responsive to the plurality of probing pulses; and determining whether there is living body contact at the contact surface with reference to change or changes in the current response parameters collected in response to the plurality of probing pulses.

The probing pulses may be voltage pulses, and the controller is to configure the probing pulse such that the current responses from a living body in bare-skin contact with the contact surface in response to the probing pulse is a current pulse having responsive current pulse characteristics of aliving body. The responsive current pulse characteristics may include a spike and a slow falling curve immediately following the spike. The falling curve may fall gradually from an initial value to an asymptotic or state-state value. The method may comprise the controller determining whether the detected current responses in response to a single probing pulse have the responsive current pulse characteristics of a living body, and generating an alert signal if the detected current responses have the responsive current pulse characteristics.

The current pulse may be a responsive current pulse having a spike, a spike peak and a spike-peak value, and the spike-peak value may be dependent on physical touching conditions of the living body with the contact surface at an instant when the current response parameters are collected from the contact surface; and the method may comprise the controller operating to collect a plurality of responsive current pulses corresponding to a plurality of different physical touching conditions.

The method may comprise the controller operating to determine whether a collected responsive current pulse comprises the responsive current pulse characteristics, and to proceed to determine whether there is living body contact at the contact surface if the responsive current pulse comprises the responsive current pulse characteristics.

The method may comprise the controller operating to determine whether changes in the responsive current pulse characteristics are consistent with changes in the physical touching conditions, and to generate an alert signal if the changes in the responsive current pulse characteristics are consistent with the changes in the physical touching conditions of a living body.

The method may comprise the controller operating to generate a plurality of probing pulses within a detection window and collecting current response parameters in response to the plurality of probing pulses, and the detection window may comprise a time duration during which physical touching conditions of the living body on the contact surface are changing.

The method may comprise the controller operating the probing circuit to generate the probing pulses such that the probing pulse has a probing-pulse duration, a probing-pulse repetition frequency, and a probing voltage amplitude such that the train of probing signals is non-harmful to a living body.

The probing pulse may have a rising edge defining start of a probing pulse and a falling edge defining end of the probing pulse, and the method may comprise the controller operating the probing circuit to generate the probing pulses such that the probing pulse has a sharp rising edge, and the probing pulse may rise from a base voltage or an off-voltage to the probing voltage in a rise-time which is a very tiny fraction of the probing-pulse duration; and the method may comprise the controller collecting current response parameters for a duration equal to, longer than or much longer than the probing-pulse duration of the probing pulse and after the end of the probing pulse.

The train of probing signals may comprise alternating on-pulses and off-pulses which are voltage pulses, the on-pulse may be a probing pulse having a base voltage level, a steady-state voltage level defining a flat probing voltage, a transition edge interconnecting the base voltage level and the steady-state voltage level, and an on-pulse duration defining a probing-pulse duration. The off-pulse may be at the base voltage level and has an off-pulse duration. The method may comprise the controller collecting current response parameters immediately after the transition edge and during the off-pulse duration.

The off-pulse duration may be longer or much longer than the on-pulse duration.

The controller may be to collect current response parameters of a current response pulse to a probing pulse at a plurality of data collection times, and the data collection times may be set at different times relative to a reference time, and the reference time may be synchronized with the probing pulse.

The controller may be to compare data amplitudes of a plurality of corresponding current response parameters collected from a corresponding plurality of current response pulses; and the controller may be to determine whether the data amplitudes show a trend of change consistent with touching conditions corresponding to a transient touch of the contact surface by aliving body.

The method may comprise detecting whether the peak current amplitude of the current responses of a plurality of sequential current response pulses increases with time, and the method may comprise using an increase of the peak current amplitude with time as an indication of possible human contact.

The method may comprise determining from the peak current amplitude of the current responses of a plurality of sequential current response pulses whether the resistance values of the first resistor decreases with time and the method may comprise using decrease of the first resistor resistance value with time as an indication of possible human contact.

The method may comprise determining from the peak current amplitude of the current responses of a plurality of sequential current response pulses whether the resistance values of the internal resistor decreases with time and the method may comprise using decrease of the internal resistor resistance value with time as an indication of possible human contact.

The current responses to be detected may include current pulse shapes of a plurality of current pulses detected or received in a sequence in response to the pulse train.

The method may comprise determining the capacitance values of the first capacitor from the current pulse shapes of the plurality of current pulses and determining whether the capacitance values of the first capacitor increase over time, and the method may comprise using increase in the capacitance value of the first capacitance with time as an indication of possible human contact at the detection surface.

The method may comprise determining whether there is possible living body contact at the electrical conductive surface with reference to change in peak currents and/or steady state currents and/or pulse shapes over time or over the plurality of voltage pulses.

The probing voltage pulse may transition from the first voltage level to the second voltage level in a transition time which is 2 μs or less, including 1.5 μs or less, 1.0 μs or less, 0.9 μs or less, 0.8 μs or less, 0.7 μs or less, 0.6 μs or less, 0.5 μs or less, 0.4 μs or less, 0.3 μs or less, 0.2 μs or less, or any range or ranges formed by combination of the aforesaid values.

The method may comprise detecting changes in the peak currents, steady state currents or other responsive current parameters within a time window of n seconds, n may be smaller than 5, including 4 or less, 3 or less, 2 or less, 1 or less, or any range or ranges formed by combination of the aforesaid values.

The probing pulse may have a pulse duration of 10 ms or less, including 8 ms or less, 6 ms or less, 5 ms or less, 4 ms or less, 3 ms or less, or any range or ranges formed by combination of the aforesaid values.

The probing pulses may be square voltage pulses having a steady state voltage, and the steady state voltage is 48V or less, including 42V or less, 36V or less, 30V or less, 24V or less, 18V or less, or any range or ranges formed by combination of the aforesaid values.

An apparatus for detecting possible living body contact at a contact surface which is an electrically conductive surface is disclosed. The apparatus comprises a controller, a probing circuit comprising a probing signal generator, a detection circuit, and a data storage device. The controller is configured to execute stored instructions to implement the methods disclosed herein.

The detection circuit may comprise data acquisition circuits to collect current response parameters at a plurality of data collection times. The data collection times are distributed at different times of current responses in response to a probing pulse.

### FIGURES

The present disclosure is described by way of example and with reference to the accompanying figures, in which:

FIG. 1 is an example circuit diagram of an example apparatus for detection of possible human contact at an electrically conductive contact surface,

FIG. 2A is an example circuit diagram of the signal amplifier of the example apparatus of FIG. 1,

FIG. 2B shows a portion of a probing signal train which comprises a plurality of probing signal pulses,

FIG. 2C shows an enlarged portion of a rising portion of a probing signal pulse of FIG. 2B,

FIG. 3A is a captured image of an example current response pulse of a living human body in physical and electrical contact with the detection surface of the apparatus of FIG. 1,

FIG. 3B is an example impedance model of a living human body,

FIG. 4 shows results of peak currents over time of a plurality of current pulses obtained from the detection surface when the detection surface is subject to a train of probing pulses and when a living human body touches the detection surface.

FIG. 4A is a diagram shown the change of values of Rₒ as extracted from the time response of FIG. 4,

FIG. 4A1 is a diagram shown the change of values of Iₚₑₐₖ vs. Rₒ as extracted from the time response of FIG. 4,

FIG. 4B is a diagram shown the change of values of R≅R₁ or R₂ as extracted from the time response of FIG. 4,

FIG. 4B1 is a diagram shown the change of values of Iₚₑₐₖ vs. R≅R₁ or R₂ as extracted from the time response of FIG. 4,

FIG. 4C is a diagram shown the change of values of C≅C₁ or C₂ as extracted from the time response of FIG. 4,

FIG. 4C1 is a diagram shown the change of values of Iₚₑₐₖ vs. R≅C₁ or C₂ as extracted from the time response of FIG. 4,

FIG. 5 is s schematic block diagram depicting an apparatus for detecting and determining contact of a living body on a contact surface.

FIG. 6A shows current response parameters of an example current response pulse when an example living body begins to touch the contact surface to which a train of probing pulses is applied,

FIG. 6B shows current response parameters of an example current response pulse in response to a probing pulse which is at a few probing probes after that of FIG. 6A,

FIG. 6C shows a plurality of current response parameters of a corresponding plurality of example current response pulses, including the current response pulses of FIGS. 6A and 6B,

FIG. 7A shows current response parameters of an example current response pulse when another example living body begins to touch the contact surface to which a train of probing pulses is applied,

FIG. 7B shows current response parameters of an example current response pulse in response to a probing pulse which is at a few probing probes after that of FIG. 7A,

FIG. 7C shows a plurality of current response parameters of a corresponding plurality of example current response pulses, including the current response pulses of FIGS. 7A and 7B, and

FIG. 8 shows an example trend of change of current response parameters during different stages of a dynamic contact with the contact surface.

### DESCRIPTION

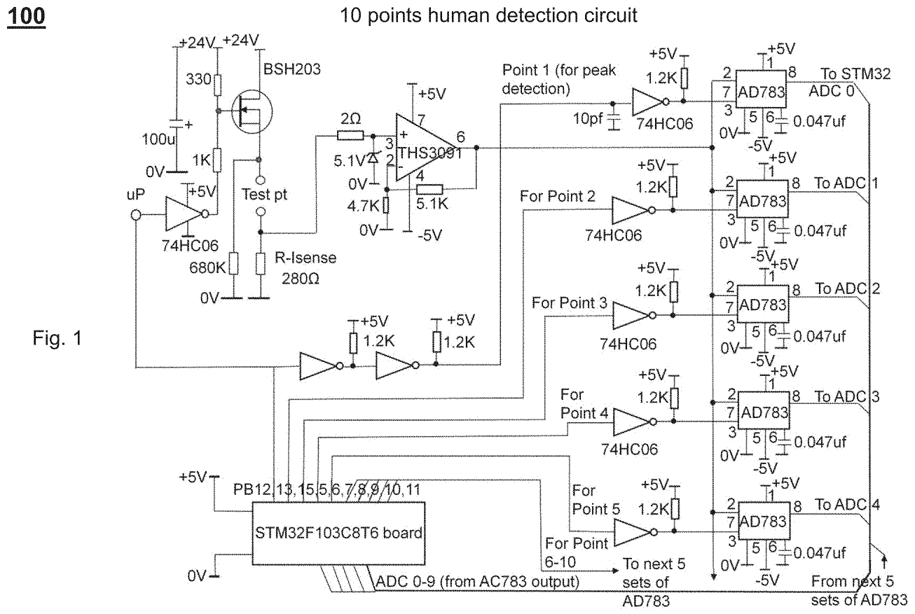

An example apparatus for detection of possible living body presence at a detection surface is depicted in FIG. 1. The example apparatus comprises a circuit arrangement which comprises a probing circuit as an example of a probing signal source, a detection circuit comprising a response signal collector, a determination circuit and a controller. In some embodiments, the controller may also function as the determination circuit.

The probing signal source comprises a probing signal generator for generating probing signals for transmission to the detection circuit. The example probing signal generator (or signal generator in short) is a microprocessor STM32F103C8T6 which is to operate at an example clock frequency of 8 MHz.

The detection circuit comprises a detection surface and a signal amplifier for amplifying probing signals which are to appear at the detection surface. The example signal amplifier is a single stage common drain voltage amplifier which is built around an example MOSFET BSH203.

A load is connected to the signal amplifier between the source terminal of the MOSFET and a voltage reference ground of the circuit. The load comprises a detection surface and a current sensing resistor R_{I_sense} which are connected in series.

The detection surface comprises a first detection surface portion and a second detection surface portion. Each of the detection surface portions is a conductive surface such as a metallic surface or a carbonized surface. The first detection surface portion is electrically connected to the source terminal of the MOSFET and the second detection surface portion which is electrically connected to the current sensing resistor R_{I_sense}. The first detection surface portion and the second surface portion are adjacently disposed and their mutually approaching proximal surface portions have surfaces which are flush to form a smooth contact surface. The first and second detection surface portions are electrically isolated and the detection surface, which is formed by the first detection surface portion and the second surface portion in cooperation and in combination, is a component having an extremely high impedance when there is no human contact to provide body impedance to interconnect the first and second detection surface portions. The example first and second detection surface portions are electrically isolated by an intermediate airgap between the mutually approaching proximal surface portions of the first and the second detection surface portions. The example detection surface has a contact area sufficient to receive the threaded portion of a thumb of an average human being.

The current sensing resistor R_{I_sense} comprises a first terminal which is an output terminal that is physically and electrically connected to the second detection surface portion and a second terminal that is physically and electrically connected to the voltage reference ground.

The drain terminal of the MOSFET is connected to a supply rail which is at a DC (direct current) supply voltage. The supply voltage rail is at an example rail voltage of 24V DC. The supply rail voltage determines the maximum output voltage of the example signal amplifier and the maximum amplitude of the detection circuit, and hence the touching voltage that a living body will be subjected to when the living body physically touches and electrically interconnects the first and the second detection surface portions. The maximum output voltage of the detection circuit may be set higher or lower. For example, the maximum output voltage of the detection circuit may be a voltage selected between 12V and 48V. An amplitude maximum of 24V has been selected empirically herein on experimental observations that living persons having more delicate skins are found to begin to feel the probing signals when the probing voltage is at 28V or higher.

The gate terminal of the MOSFET is the signal input terminal of the signal amplifier. The input of the signal amplifier is connected to the probing signal source by means of an example buffer circuit and an example resistor bridge. The example resistor bridge comprises a pull-up resistor having an example resistance value of 3300 and a pull-down resistor having an example resistance value of 1 kΩ which are connected in series. The example buffer circuit is a buffered inverter of a 74HC06 IC. The input of the buffered inverter is connected to the probing signal generator output, which is an output port PB12 of the microprocessor. The output of the buffered inverter is connected to an input terminal of the pull-down-resistor and the output terminal of the pull-down resistor is connected to both the gate terminal of the MOSFET and the pull-up resistor. The terminal of the pull-up resistor which is not connected to the gate terminal of the MOSFET is connected to the 24V supply rail. With a signal amplifier stage connected between the probing signal source and the detection surface, the maximum amplitude of the probing signal is amplified from the example voltage amplitude of 5V at the probing signal generator output PB12 to the maximum amplitude of the example supply rail voltage of 24V at the detection surface.

The detection circuit is electrically coupled to a signal collection circuit so that responsive signals resulting from living body touching at the detection surface will be electrically coupled to a signal collection circuit for collection and recording. The collected responsive signal data will be analyzed by a determination circuit to determine whether there is human contact at the detection surface. The signal collection circuit comprises sampling circuits to obtain samples of the responsive signals.

The example signal collection circuit comprises an assembly of sample-and-hold devices which comprises an example plurality of ten sample-and-hold devices to collect sample data at ten different times. The example sample-and-hold devices used are monolithic sample-and-hold amplifiers AD783 having an acquisition time of about 250 ns. Each sample-and-hold circuit is configured to acquire an output data at a specific time and the assembly of sample-and-hold devices is configured to collect a plurality of output data of the detection circuit at a corresponding plurality of data collection times. The example signal collection circuit comprises an example plurality of ten sample-and-hold devices and the ten sample-and-hold devices are configured to acquire data at ten different times. The data collection times are distributed at different times in order to capture time domain signal response at the detection surface in response to the probing signals at the detection surface. The data collection times may be distributed with respect to the timing of the probing signal pulses in order to detect time domain responses. In some embodiments such as the present, the data collection times are set relative to the rising edge of the probing signal pulse, for example, at beginning or end of the rising edge.

The data collection times, also known as the data capture or acquisition times, of each sample-and-hold device of the example signal collection circuit are controlled by the microprocessor.

Each sample-and-hold circuit is to operate to capture and hold a data when a data acquisition signal appears at a triggering terminal pin 7 of the sample-and-hold circuit. The triggering terminal is connected to an output port of the microprocessor. In the example circuit arrangement of FIG. 1, output ports PB12, PB13, PB15, PB5, PB6, PB7, PB8, PB9, PB10 and PB11 are connected, respectively, to sample-and-hold circuits numbered 1, 2, 3, 4, 5, 6, 7, 8, 9 and 10 via at least a buffer circuit 74HC06. When a data acquisition signal S appears at pin 7, the sample-and-hold circuit will be triggered to operate to capture the data which is a voltage amplitude appearing at the data input terminal (pin 2) of the sample-and-hold circuit. The data input terminals (pin 2) of the assembly of sample-and-hold circuits are all connected to a signal input node which is a common signal input node but are arranged to capture data at different times of a response pulse for pulse characterization.

After a data has been acquired, the data will be held by the sample-and-hold circuit and appear at the data output terminal 8. To facilitate transfer of captured data to the microprocessor, the output terminal pin 8 of the sample-and-hold circuit is connected to data input port (ADC ports 0-9) of the microprocessor. After a data has been captured, the data captured by the sample-and-hold circuit will be held by the sample-and-hold circuit for as long as terminal 7 of the sample-and-hold circuit is maintained at a hold state. After the held data has been collected by the microprocessor, the sample-and-hold circuit will be ready for the next data capture.

The first sample-and-hole circuit is connected to port PB12, which is also the probing signal output port. A pair of inverters is introduced between the buffer circuit and port PB12 as a delay circuit to compensate for signal path delay which is introduced by the signal amplifier and its frontend circuits so that the data capture time is synchronized or substantially synchronized with the peak of the rising edge of the probing signal pulse and with the pulse peak of the response current pulse which is characteristic of living body contact at the detection surface when subject to the probing signal pulse. A 10 pF capacitor is added to the input terminal of the buffer circuit 74HC06 which is directly connected to the first sample-and-hold circuit to provide sufficient delay compensation. The capture times of the 2^{nd} to the 10^{th} sample-and-hold circuits are set sequentially relative to the capture time of the first sample-and-hold circuit in this example. In some embodiments, the capture times of the other sample-and-hold circuits are set with respect to timing of the probing signal pulse, for example, with respect to the beginning of change (say rise) from a base level or beginning of change from a changing (say rising) edge into a settling level.

The responsive signals which will occur at the detection surface when there is conductive contact at the detection surface are to be collected by the signal collection circuit for data acquisition and subsequent processing by the determination circuit. To facilitate data acquisition, the output of the detection circuit is electrically coupled to the input of the signal collection circuit. For this purpose, the example signal collection circuit comprises a signal input node which is connected to the output node of the detection circuit so that responsive signals originating from the detection surface can be captured by the signal collection circuit for storing in a memory device controlled by the controller.

As depicted in FIG. 1, the output terminal of the current sensing resistor R_{I_sense} is electrically connected to the signal input node of the signal collection circuit via an intermediate circuit. The intermediate circuit comprises an amplification and buffered stage comprising an example operational amplifier THS3091 which interconnects the output node of the detection circuit and the input node of the signal collection circuit.

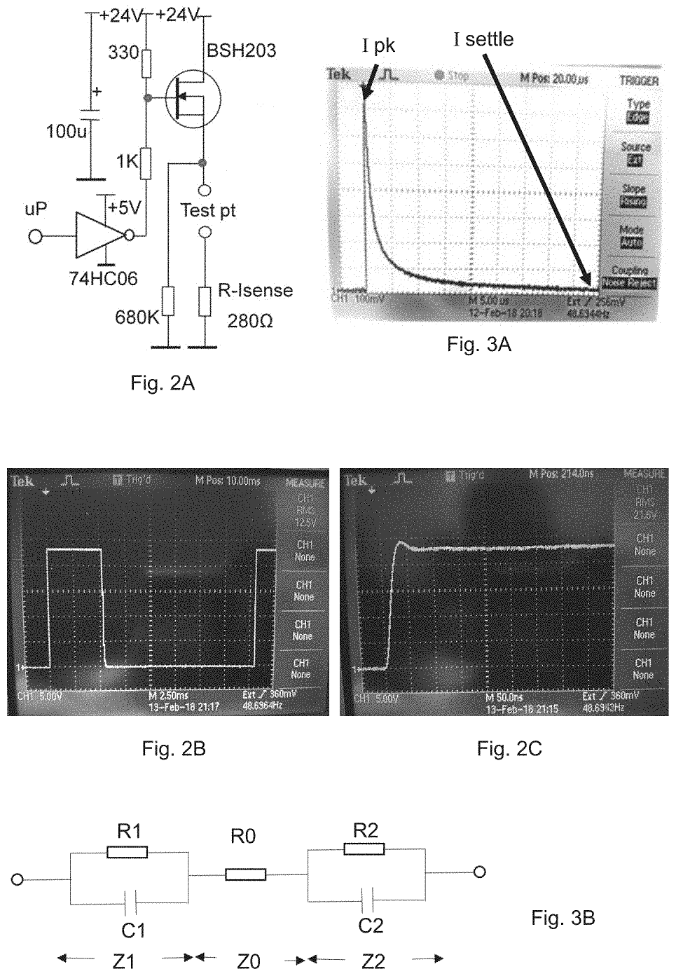

The probing signals to be sent to the detection surface are arranged as a train of probing signals. Referring to FIGS. 2A, 2B and 2C, the microprocessor is to generate a train of probing signals and the signal amplitudes of the probing signals are amplified by the signal amplifier for output at the first detection surface portion. The example probing signal pulse train comprises alternating on-pulses and off-pulses. Each on-pulse has a rising edge, a falling edge, an on-pulse duration, and is at a probing voltage level between the rising and falling edges. Each off-pulse has a falling edge, a rising edge, an off-pulse duration, and is a base voltage level between the falling and rising edges. The on-pulse duration is delimited by the rising and falling edges and is typically a millisecond or a plurality of milliseconds, but usually not exceeding 2-3 milliseconds. The off-pulse duration is delimited between the falling and rising edges and is typically 5-20 milliseconds, but usually not exceeding 20 milliseconds to permit skin recovery while allowing a plurality of pulse response readings to be taken within a short probing time to mitigate user perception or discomfort. The example on-pulses are identical square pulses and adjacent probing signal pulses are at uniform time separation or uniform time spacing.

Each probing signal is a signal pulse having a base amplitude which is the voltage amplitude of the base voltage level, a peak amplitude or steady-state amplitude which is the voltage amplitude of probing voltage level, and a pulse width or a pulse period corresponding to the on-pulse duration. The example signal pulse is a square pulse having an example signal duration or pulse width of 5 ms, an example space width of 15 ms and an example mark and space ratio of 1:3. In other embodiments, the mark and space ratio can be 1:5 or less, 1.4 or less, 1:3 or less, 1:2 or less, or any range or ranges formed by combination of the aforesaid values.

The example probing signal pulse rises from the base amplitude to the peak amplitude in a very short time (around 100 ns-200 ns) and stays at the peak voltage for a duration (which is 5 ms in the example) which is substantially or significantly longer than the rise-time. The probing signal pulse returns from the peak amplitude to the base amplitude at the end of the pulse width duration.

When a living body makes contact with the detection surface, for example, touching its thumb on the first and second detection surface portions simultaneously to close the air-gap between the first and second detection surface portions, thereby changing or reducing the impedance at the detection surface, a response signal pulse will be detected. The example response signal pulse is a current pulse since the parameter being monitored is the current which flows through the current sensing resistor R_{I_sense}.

A typical response signal which will occur at the detection surface in response to a probing pulse according to the present disclosure when there is living body touch has a typical pulse shape as depicted in FIG. 3A. The signal response is characteristic of human contact and the response is consistent with the human impedance model as depicted in FIG. 3B.

The example human impedance model comprises a first resistor R₁, a second resistor R₂, a first capacitor C₁, a second capacitor C₂ and an internal resistor R₀. The impedance model comprises a first RC bridge R₁C₁ comprising a parallel connection of the first resistor R₁ and the first capacitor C₁, a second RC bridge R₂C₂ comprising a parallel connection of the second resistor R₂ and the second capacitor C₂, and the internal resistor R₀ interconnecting the first RC bridge and the second RC bridge.

A probing signal having a very sharp rising edge, which is a transition edge, such that the signal pulse changes from the base amplitude to the peak amplitude within a very short time means that the transitional portion of the probing signal has a very high frequency signal component sufficient to bypass the shunt capacitors C₁& C₂ of the human impedance mode as depicted in FIG. 3B. The peak current amplitude Iₚₑₐₖ of the response current would be equal to V_{touch}/R₀, where V_{touch} is the effective amplitude of the probing voltage appearing at the detection surface and is approximately equal to the supply rail voltage which is 24V in this example. For an average living human body, a rise-time of about 100 ns, 150 ns or 200 ns or less is found to produce consistent and reliable peak current values. In general, a rise-time of 5 μs or less, for example, 4 μs or less, 3 μs or less, 2 μs or less, 1 μs or less, 800 ns or less, 500 ns or less, 400 ns or less, 300 ns or less, 200 ns or less, 100 ns or less, or a range or any ranges formed by combination of the aforesaid values are found to be useful for characterizing aliving human body. It is believed that a rise-time which is sufficiently short (and therefore a rising edge which is sufficiently sharp) to produce a valid peak current amplitude Iₚₑₐₖ would be shorter than the characteristic rise-time of the human impedance model, the characteristic rise-time of the first RC bridge, the characteristic rise-time of the second RC bridge, or the shortest one of the aforesaid rise-time without loss of generality.

The choice of the value of the effective probing voltage or V_{touch} is a balance or compromise between minimal hazard to the living body and a meaningful response signal amplitude. In general, a touching voltage of between 10V and 28V would be acceptable. In some embodiments, the touching voltage V_{touch} may be set as high as 48V to 50V, but the duration should be sufficiently short, for example, less than 1 second. In order to mitigate potential hazards to a living human body, the probing voltage and the probing current are to be limited to a non-hazardous range. The probing voltage, probing-voltage duration and the probing pulse repetition frequency are selected to minimize or mitigate living body perception or possible harm. In order that the presence of a living body at a conductive contact surface being applied with a train of probing signals can be determined swiftly so that operation of an electrical appliance or alike will not be unduly delayed, it is desirable that a plurality of probing pulses is transmitted, received and analyzed within a short duration, for example, in a second or a few seconds. On the other hand, a living body needs to recover or relaxed from the last probing signal application to produce accurate or reliable data collections, adjacent probing pulses should be separated by a time equal to or larger than the characteristic relaxation time of (the skin of) a living body. An off-duration of about 5-10 milliseconds between adjacent on-pulses has been found to be reasonably satisfactory for achieving probing reliability, and a probing pulse repetition frequency in the region of 10-50 probing pulses per second has been found to be useful. In general, the probing pulse repetition frequency may be selected as 10, 15, 20, 25, 30, 35, 40, 45, 50 probing pulses per second or any ranges selected from any combination of the aforesaid values as boundaries.

A probing voltage pulse which stays at the peak or steady-state voltage level for a sufficiently long duration would result in a steady-state current I_{steady_state} having a current amplitude equal to V_{touch}/R_{T}, where R_{T}=R₀+R₁+R₂. The steady-state current I_{steady_state} is marked Iₛₑₜₜₗₑ in FIG. 3A. It is believed that a duration of the steady-state voltage level which is sufficiently long to produce a valid steady-state current I_{steady_state} would be longer than the characteristic fall-time of the human impedance model, the characteristic fall-time of the first RC bridge, the characteristic fall-time of the second RC bridge, or the longest one of the aforesaid fall-times without loss of generality. In general, the duration of the peak or steady-state voltage level of the touching voltage would be at least ten, hundreds or even thousand times the longest one of the aforesaid fall-times. For an average living human body, a steady-state voltage level duration of about 50 μs or more would be sufficient.

In example embodiments, the data collection times of the plurality of sample-and-hold circuits are sequentially set to be at: current peak (delay by circuit RC delay) as time 0 or reference time, 0.7 us, 1.4 us, 2.1 us, 3 us, 5 us, 8 us, 15 us, 30 us, 50 us, relative to or from the reference time.

It will be appreciated that the data collection times are more crowdedly placed near the reference time or time zero where the current peak is located and more scarcely distributed on moving away from the reference zero since the signal changes occur much more faster near time zero due to the current spike or the spike shape of the response current pulse which is characteristic of a living human body.

In example embodiments, the sampling time intervals near the time where the spike of the response signal occurs would be preferably at around several hundred nanoseconds, for example, 200 ns-500 ns, as this is the region of more rapid change in current response.

In practice, a steady-state voltage level duration (or on-pulse duration) of about 50 μs or more, 100 μs or more, 150 μs or more, 200 μs or more, 250 μs or more, 300 μs or more would be sufficient. In order to obtain a sufficient number of response samples within a small probing time window, the steady-state voltage level duration of a probing voltage pulse would be shorter than 10 ms, 5 ms, or 1 ms. Therefore, the pulse width of a probing voltage is likely to be a range selected from a combination of the values 50 μs or more, 100 μs or more, 150 μs or more, 200 μs or more, 250 μs or more, 300 μs or more and 10 ms or less, 5 ms or less, or 1 ms or less without loss of generality.

The time spacing between adjacent probing pulses is selected to provide sufficient recovery time to the living body so that its body impedance characteristics resume to their normal responsive state before the next probing pulse arrives. For a non-hazardous probing voltage herein, the recovery time is believed to be one mini-second (1 ms) or less. In practice, a time spacing of at least several mini-seconds is set to ensure adequate recovery of body impedance state under non-hazardous probing voltage and probing current conditions.

In general, a probing pulse train comprising a plurality of square edged probing pulses having a probing voltage amplitude of an effective but non-hazardous value, a fast enough rising time, a sufficiently long steady state, and a sufficiently long inter-pulse spacing would be desirable for living human body detection.

In example embodiments, a square pulse train comprising between 5 and 40 pulses in a probing window having a time duration of 1-2 seconds, wherein each pulse has a steady state probing voltage of between 10V and 30V, a rise-time shorter than the aforesaid rise-time, a steady-state voltage level duration within the aforesaid range and a time spacing between adjacent probing pulses within the aforesaid range would be desirable.

For the human body impedance model of FIG. 3B, the impedance of the various components of the impedance bridge can be expressed as below:

$${Z}_{1} = \frac{{R}_{1}}{1 + s {C}_{1} {R}_{1}} \\ {Z}_{2} = \frac{{R}_{2}}{1 + s {C}_{2} {R}_{2}}$$

$${Z}_{0} = {R}_{0}$$

$$V = IZ , Z = {Z}_{1} + {Z}_{2} + {Z}_{0}$$

The transfer function of the impedance bridge can be expressed as:

$$\frac{I ( s )}{V ( s )} = \frac{{a}_{2} {s}^{2} + {a}_{1} s + {a}_{0}}{{b}_{2} {s}^{2} + {b}_{1} s + {b}_{0}} , where$$

$${a}_{2} = {C}_{1} {C}_{2} {R}_{1} {R}_{2} , {a}_{1} = {C}_{1} {R}_{1} + {C}_{2} {R}_{2} , {a}_{0} = 1$$

$${b}_{2} = {C}_{1} {C}_{2} {R}_{1} {R}_{2} {R}_{0} , \\ {b}_{1} = {C}_{2} {R}_{1} {R}_{2} + {C}_{1} {R}_{1} {R}_{2} + {C}_{2} {R}_{2} {R}_{0} + {C}_{1} {R}_{1} {R}_{0} , {b}_{0} = {R}_{1} + {R}_{2} + {R}_{0}$$

The step response can be expressed as:

$$\begin{matrix}I ( s ) = \frac{V}{s} \cdot \frac{{a}_{2} {s}^{2} + {a}_{1} s + {a}_{0}}{{b}_{2} {s}^{2} + {b}_{1} s + {b}_{0}} \\ = \frac{V}{s} \frac{{a}_{0}}{{b}_{0}} + \frac{V ( α s + β )}{{b}_{2} ( s - {p}_{1} ) ( s - {p}_{2} )} \\ = \frac{V}{s} \frac{{a}_{0}}{{b}_{0}} + \frac{V {k}_{1}}{( s - {p}_{1} )} + \frac{V {k}_{2}}{( s - {p}_{2} )}\end{matrix}$$

$$where$$

$${p}_{1 , 2} = - \frac{{b}_{1}}{2 {b}_{2}} \pm \sqrt{{( \frac{{b}_{1}}{2 {b}_{2}} )}^{2} - \frac{{b}_{0}}{{b}_{2}}}$$

$${k}_{1} = \frac{{p}_{1} α + β}{\sqrt{( {b}_{1}^{2} - 4 {b}_{0} {b}_{2} )}}$$

$$α = \frac{{a}_{2} {b}_{0} - {a}_{0} {b}_{2}}{{b}_{0}}$$

$${k}_{2} = \frac{- {p}_{2} α - β}{\sqrt{( {b}_{1}^{2} - 4 {b}_{0} {b}_{2} )}}$$

$$β = \frac{{a}_{1} {b}_{0} - {a}_{0} {b}_{1}}{{b}_{0}}$$

Inverse Laplace transform of the above would give a time domain solution (1) of the second order network.

Second Order ODE Solution

$$i ( t ) = V ( t ) [ \frac{{a}_{0}}{{b}_{0}} + {k}_{1} {e}^{- {p}_{1} t} + {k}_{2} {e}^{- {p}_{2} t} ] \qquad ( 1 )$$

First Order ODE Solution

Assuming R₁=R₂=R and C₁=C₂=C, The second order network can be represented by a first order differential equation, and the step response of the impedance network would become:

$$I ( s ) = \frac{V}{s} \cdot \frac{1 + sCR}{{R}_{0} + 2 R + sCR {R}_{0}}$$

The solution of the above equation is:

$$i ( t ) = \frac{v ( t )}{( {R}_{0} + 2 R )} + \frac{2 R}{{R}_{0}} \cdot \frac{v ( t )}{( 2 R + {R}_{0} )} {e}^{- \frac{t ( 2 R + {R}_{0} )}{{CRR}_{0}}} \qquad ( 2 )$$

The time constant

$$τ = \frac{C R {R}_{0}}{( 2 R + {R}_{0} )} .$$

The values of R and C can be obtained by approximation and curve matching from a measured pulse response of FIG. 3A.

In example operations, a plurality of probing response signals over a short probing window duration in response to the train of probing signals is obtained and analyzed for determination of possible human contact.

In example embodiments, a plurality of responsive current pulses within a probing window is collected for analyses and determination.

A set of example results obtained from response of an example living human body to a probing signal train and captured by the signal collection circuit and same example parameters extracted therefrom are tabulated below in Table 1.

TABLE 1

| | | | | | | v (t) | t | |
|---|---|---|---|---|---|---|---|---|
| | | | | | 10% | 20% | 20% | C |
| Data | | | | (R1 + R2)/ | Vpeak | Vpeak | Vpeak | C1/C2 |
| file | Vpeak | Vsettle | R0 | 2 = R (0) | (uS) | (V) | (uS) | (pF) |
| Ann018 | 0.99 | 0.01 | 6,508 | 665,212 | 2.7 | 0.198 | 0.93 | 167.65 |
| Ann028 | 1.51 | 0.02 | 4,170 | 331,550 | 2.6 | 0.3 | 0.9 | 245.21 |
| Ann035 | 1.99 | 0.03 | 3,097 | 220,623 | 2.4 | 0.4 | 0.9 | 324.60 |
| Ann042 | 2.3 | 0.035 | 2,642 | 189,078 | 2.2 | 0.46 | 0.9 | 373.85 |
| Ann053 | 2.74 | 0.04 | 2,173 | 165,547 | 1.8 | 0.548 | 0.9 | 445.77 |

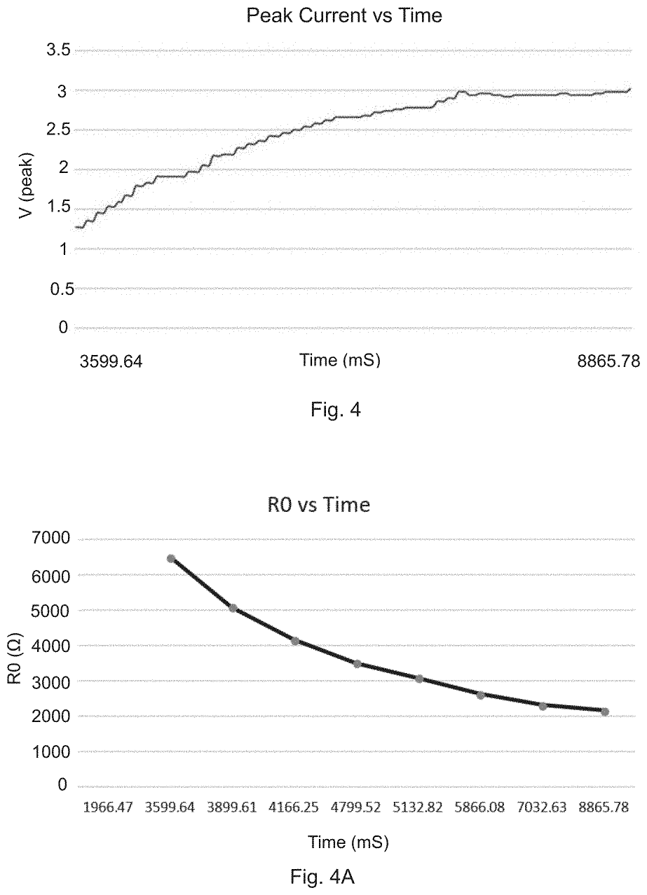

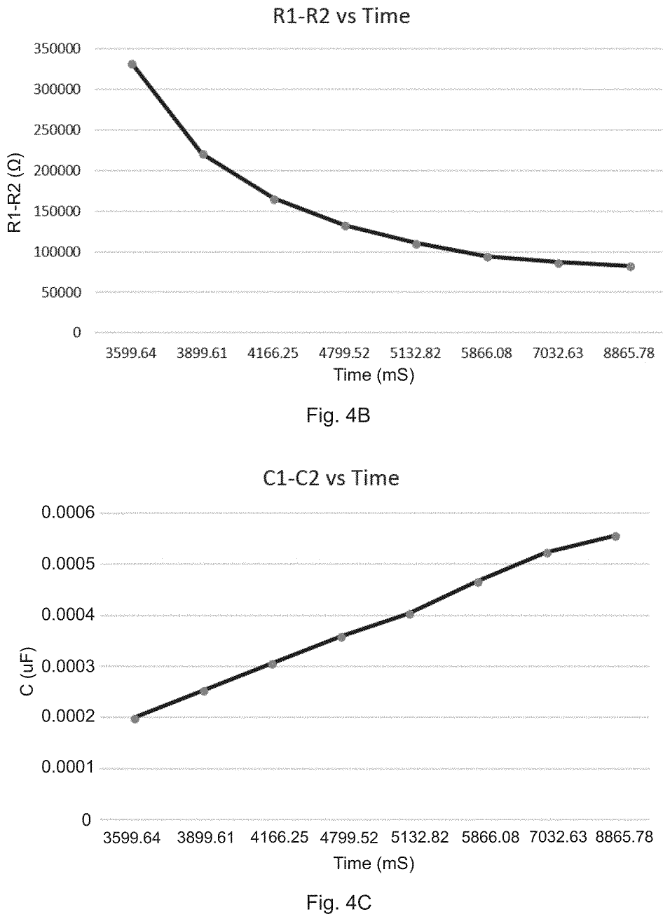

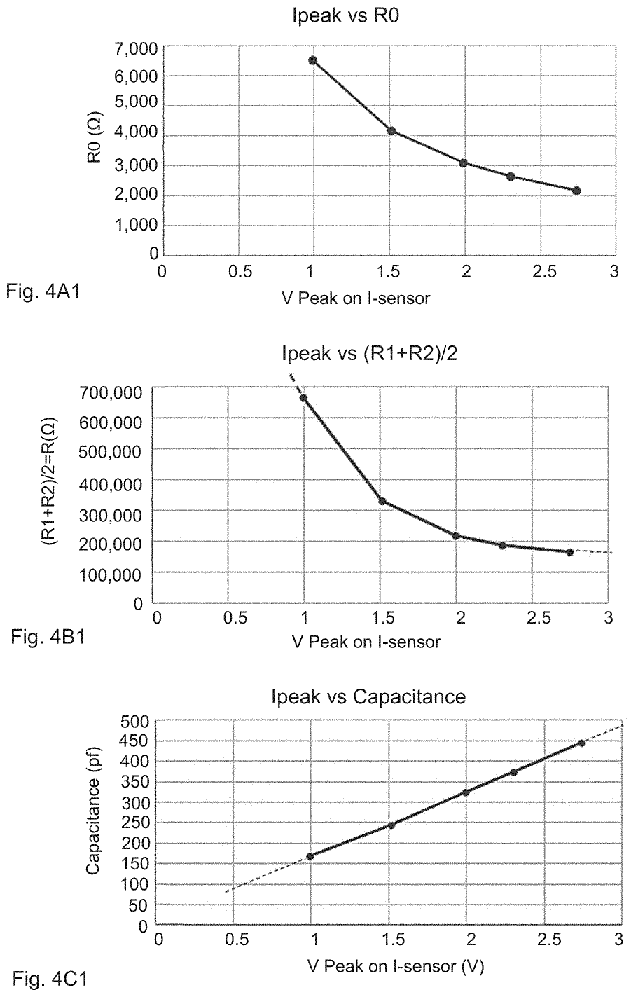

The current responses of FIG. 4 are the peak current amplitudes of a plurality of response signal pulses measured over a period of time in response to a train of probing pulses applied to the detection surface when a living human body begins to touch the detection surface. It is observed from the current responses that the peak current amplitudes change over time.

It is also observed that the peak current amplitude (as represented by the peak voltage at the output terminal of the current sensing resistor) increases as time of contact increases.

FIG. 4A shows changes of R₀ over the same time window. The value of R₀ is estimated from the peak current amplitude using the relationship Iₚₑₐₖ=V_{touch}/R₀. It is observed that the value of R₀ falls as time of contact increases.

FIG. 4B shows changes of R=R₁ over the same time window. The value of R is estimated from the peak current amplitude using the relationship Iₛₑₜₜₗₑ=V_{touch}/R_{T} and R_{T}=R₀+R₁+R₂=R₀+2R, where R≈R₁≈R₂. It is observed that the value of R₁ falls as time of contact increases.

FIG. 4C shows changes of C=C₁ over the same time window. The value of C is estimated from the pulse response shape using the relationship

$$τ = \frac{C R {R}_{0}}{( 2 R + {R}_{0} )} .$$

It is observed that the value of C increase as time of contact increases.

The above observations can be used to facilitate determination of possible human contact at the detection surface.

In some embodiments, the probing signal train may be modulated on a carrier signal. The probing signal train may comprise a plurality of square probing voltage pulses and the carrier signal may be a sinusoidal voltage wave train. For example, the probing signal train may be a train of probing signal pulses described herein and the carrier signal may be a sinusoidal wave train having a frequency of 50 Hz or 60 Hz. The carrier signal may be compatible with the mains power supply of say, for example, 110V or 220V RMS, or at a lower voltage amplitude, for example, at 12V rms, 24V rms, 36V rms, etc. without loss of generality.

The current responses to the modulated probing signal pulses measured at the detection surfaces can be recovered from the current response for analyses and determination after filtering of the sinusoidal components without loss of generality.

While example application and utilization of the various observations and phenomenon have been described with examples herein, it should be appreciated that other applications and utilizations are possible without loss of generality and the example applications and utilizations are intended to provide non-limiting examples.

The present disclosure discloses methods and apparatus for detecting whether there is living body contact on an electrically conductive surface. The methods can be implemented using electronic circuits controlled by a controller. The controller may be a microprocessor-based controller or logic arrays which is to execute stored instructions corresponding to the methods disclosed herein.

By selecting an appropriate probing pulse such that application of the probing pulse on a living body will return a responsive current pulse bearing characteristic electrical properties of a living body, applying the probing signal on a contact surface, monitoring the contact surface with a signal detection circuit, and determining whether electrical parameters representing a responsive current pulse bearing characteristic electrical properties of a living body are received from the contact surface. If electrical parameters representing a responsive current pulse bearing characteristic electrical properties of a living body are received from the contact surface, the physical bare-skin contact of a living body with the contact surface can be positively determined and immediate remedial measures, for example, triggering of an alarm signal, an alert signal, a power stop or a power-stop signal, and/or a rescue signal, can be implemented to mitigate harm injury and damage.

In addition to determining whether a responsive current pulse bearing characteristic electrical properties of a living body has been received, electrical parameters of a plurality of responsive current pulse due to a plurality of probing pulses in the train of probing signals are also collected and examined to determine whether there are dynamic behaviors suggesting living body touch, or more exactly dynamic or transient living body touch, on the contact surface. If phenomenon corresponding to the dynamic touching behaviors are detected in addition, there is additional certainty that there is living body contact (bare skin contact) on the contact surface.

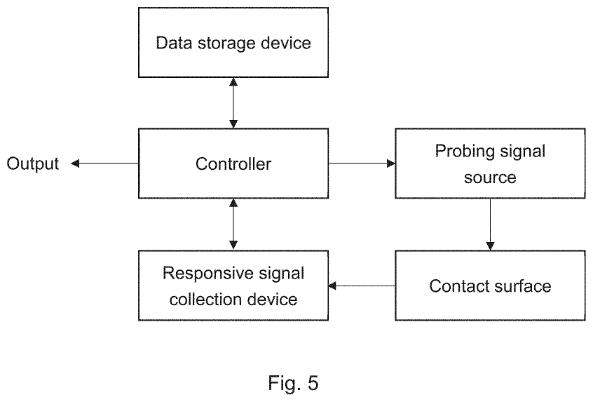

An example apparatus which is for determining whether there is living body contact at an electrically conductive surface is depicted in FIG. 5. The apparatus comprises a probing signal source, a response signal collector, a controller, and a data storage device. The probing signal source is for generating probing signals, and the probing signals are designed to attract responsive electrical signals which embody characteristic electrical properties of a living body.

The example probing signal source, response signal collector and detection circuit of FIG. 1 may be used to form the circuitry part of the example apparatus of FIG. 5 without loss of generality. While the response signal collector may be part of the controller, a hardware-based data collection circuit forming part of the response signal collector may be desirable due to speed advantages of high-speed electronic circuitry, since initial data may need to be collected in a region of 100 ns-200 ns.

In order to collect electrical parameters from the contact surface for determination of whether the electrical parameters correspond to electrical parameters of a living body at the contact surface, a sufficient number of responsive electrical data needs to be collected. In the present example, a responsive current pulse having a characteristic current pulse shape of aliving body is expected. The characteristic current pulse shape of aliving body comprises a spike and a slow falling curve which falls from the peak of the spike to a steady state. The spike is almost instant and rises from a spike base to a spike peak almost instantly or at the same time when the probing pulse rises to the probing voltage level. In general, there is a typically lag of between 50 ns-150 ns between the spike peak and the rising edge of the probing pulse. The spike peak has a value which is substantially higher than the asymptotic steady state value. The fall comprises a sharp or rapid fall which is then followed by a slow fall. The sharp fall starts immediately after the spike peak short duration and the slow fall extends for a much longer duration, for example, typically takes one or more than one on-pulse duration and sometime more than 2 or 3 or 4 on-pulse durations to reach an asymptotic steady state. For this reason, the off-pulse duration of the train of probing signals may be selected to be at least a few on-pulse durations.

In order to collect sufficient data to construct the responsive signal and to facilitate determination whether the responsive signal has electrical characteristics of characteristic current pulse shape of aliving body, a plurality of responsive signal data for each probing pulse is required. The more responsive signal data is of course better but the time and processing overhead may not justify collection of a large number of responsive signal data. In general, an example plurality of say 10-20 data collection points, including at least a data collection point at or near the spike peak, a data collection point at or near the steady-state level, a date collection point at or near where the fall changes from a rapid fall to a slow fall, and data collection points between the aforesaid salient data collection points would be useful. For example, the data collection points may further include one data collection point of a plurality of data collection points on the sharp fall portion, and a plurality of data collection points on the slow fall portion.

The data collection points may be set at times relative or with respect to the probing pulse as a reference time. For example, the data collection points may be set at relative time delays with respect to the rising edge, for example, beginning, middle or end of the rising edge. The first data collection point may be set at the time when the rising edge of the probing pulse and this would facilitate capture of the spike peak value. The initial data collection points are more densely distributed to facilitate data collection during the rapid fall stage. The data collection points after the initial microsecond or a few microseconds may be more sparsely distributed. The data collection circuit may be set to be in synchronization with the rising edge of the probing signal and begins to collect responsive signal data in synchronization with the rising edge of the probing signal without loss of generality.

With the collection of data during the on-pulse duration and the off-pulse duration immediately after the last ended on-pulse, the controller would have sufficient data to determine with reference to the received responsive current signals whether there is living body contact at the contact surface.

In addition to determining whether there is living body contact at the contact surface by comparing detected current shape with an expected current pulse shape in response to the probing pulse, the controller may further or optionally determine whether there is dynamic phenomenon indicating human touch at the contact surface.

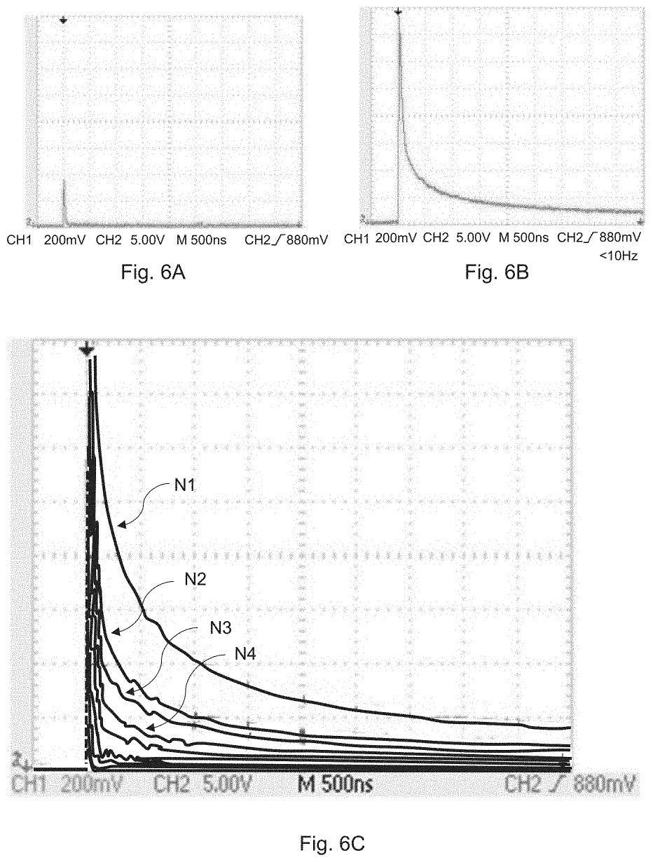

It is observed from example response current pulses shown in FIGS. 6A, 6B and 6C that the response current pulses at an initial period of touch when aliving body begins to get into contact with the contact surface are somewhat different at different times. For example, it is noted that the current pulse has a smaller size and a lower spike when the touch just begins and the current pulse has a lager size and a higher spike after the touch has begun for a short while, for example, after 100 ms. The example response diagram of FIG. 6A is taken at a first touching time t₁ which is close to the time to of initial touch such that t₁>t₀. An initial touch means the living body was not in bare-skin contact with the contact surface but comes into contact at the initial touch, which is given an initial time reference of t₀. The example response diagram of FIG. 6B is taken at a second touching time t₂ which is after the first touching time, that is, t₂>t₁. An initial touch means the living body was not in bare-skin contact with the contact surface but comes into contact at the initial touch, which is given an initial time reference of t₀. The data collection times, for example, t₂, t₁ etc. are with respect to the probing pulse time.

The trend of changes is shown in FIG. 6C, in which N4 is one of the earlier pulses and N1 is a steady-state spike after 100-200 ms.

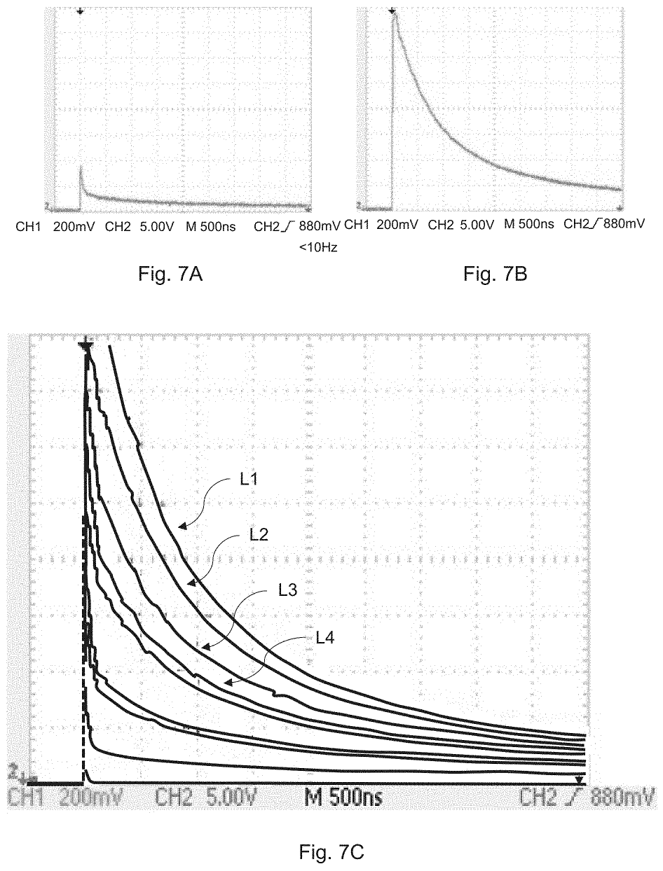

A same trend of responses is also observed with another living body, as depicted in FIGS. 7A, 7B and 7C. The example response diagram of FIG. 7A is taken at a first touching time t₁ which is close to the time to of initial touch such that t₁>t₀. The response diagram of FIG. 7B is taken at a second touching time t₂ which is after the first touching time, that is, t₂>t₁. An initial touch means the living body was not in bare-skin contact with the contact surface but comes into contact at the initial touch, which is given an initial time reference of t₀.

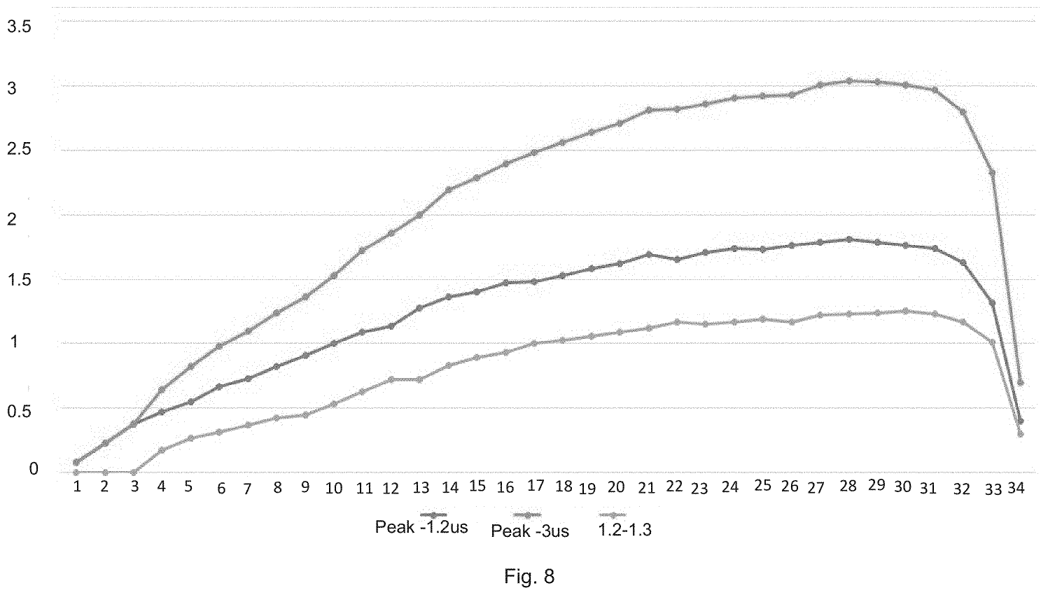

Example values of responsive current data of an example living body taken at the plurality of data collection times and a plurality of touching times t₃, t₂, t₁, are tabulated in FIG. 8. The lowest or innermost curve is taken at a time t₁ which is near a time to of initial touch. The highest or outermost curve is taken at time t₃ which is well after touch has begun. The middle or intermediate curve is taken at time t₂ which is intermediate t₃ and t₁.

Each curve is constructed using data collected at different data collection times at different times of a responsive current pulse. In this example, each curve is constructed using 34 data collected from an example plurality of 34 data collection times which are distributed along the duration of a responsive current pulse.

It is noted from FIG. 8 and the amplitude at most data collection times increases initially with increase in touching time, and then decreases with further increase in touching time, indicating that the data values come to a steady state value after certain touching time.

It is further noted that the amplitude increase is more significant at the data points near the middle of the curve, or before the curve reaches a maximum.

The above trends may be utilized by the controller to determine whether there is dynamic touching behavior of a living body.

It is believed that the dynamic touching behaviors occurs due to touching dynamics, since when a living more just begins to touch a contact surface, the pressure is low and this would translate into a higher body resistance and/or a lower capacitance and hence a smaller & sharper pulse having a lower spike peak amplitude. When the touch moves some what deeper, for example, in several milliseconds, the pressure increases. The increase in pressure also increases touching area as well as a better contact, resulting in a larger current pulse and a higher spike peak value. When the touch comes into a steady state, the current pulse has a somewhat steady state and no significant changes can be seen after that.

For example, the controller can examine the collected data whether the data collected at corresponding data collection times has an increasing trend and to give positive determination when an increasing trend is detected.

In this disclosure, a living body has a contact portion having electrical properties resembling an impedance bridge comprising a plurality of resistors and a plurality of capacitors connected in series and parallel and having a characteristic rise-time and a characteristic fall-time. The impedance bridge comprises a resistor series (R₀+R₁+R₂) having a total resistance value and a resistor-capacitor first RC bridge comprising a parallel connection of a first resistor (R₁) having a first resistance value and a first capacitor (C₁) having a first capacitance value. The resistor series (R₀+R₁+R₂) comprise an internal resistor (R₀) in series connection with the first RC bridge and having an internal resistance value.

1. A method of detecting possible living body contact at an electrical conductive surface, wherein the living body has a contact portion having electrical properties resembling an impedance bridge comprising a plurality of resistors and a plurality of capacitors connected in series and parallel and having a characteristic rise-time and a characteristic fall-time, wherein the impedance bridge comprises a resistor series (R₀+R₁+R₂) having a total resistance value and a resistor-capacitor first RC bridge comprising a parallel connection of a first resistor (R₁) having a first resistance value and a first capacitor (C₁) having a first capacitance value, and the resistor series (R₀+R₁+R₂) comprises an internal resistor (R₀) in series connection with the first RC bridge and having an internal resistance value; and wherein the method comprises:
sending a pulse train of voltage pulses to the contact surface, wherein the pulse train comprises a plurality of voltage pulses as probing pulses and each voltage pulse has a sharp edge which changes from a first voltage level which is a base voltage level to a second voltage level, and a flat region at the second voltage level;
detecting current responses from the contact surface to the pulse train; and
determining whether there is possible living body contact at the electrical conductive surface with reference to the current responses.

2. The method of claim 1, wherein the current responses to be detected include peak currents of a plurality of current pulses detected or received in response to the pulse train.

3. The method of claim 1, wherein the current responses to be detected include steady state currents of a plurality of current pulses detected or received in response to the pulse train.

4. The method according to claim 1, wherein the method comprises detecting whether the peak current amplitude of the current responses of a plurality of sequential current response pulses increases with time, and wherein the method comprises using an increase of the peak current amplitude with time as an indication of possible human contact.

5. The method according to claim 1, wherein the method comprises determining from the peak current amplitude of the current responses of a plurality of sequential current response pulses whether the resistance values of the first resistor decreases with time and wherein the method comprises using decrease of the first resistor resistance value with time as an indication of possible human contact.

6. The method according to claim 1, wherein the method comprises determining from the peak current amplitude of the current responses of a plurality of sequential current response pulses whether the resistance values of the internal resistor decreases with time and wherein the method comprises using decrease of the internal resistor resistance value with time as an indication of possible human contact.

7. The method according to claim 1, wherein the current responses to be detected include current pulse shapes of a plurality of current pulses detected or received in a sequence in response to the pulse train.

8. The method of claim 7, wherein method comprises determining the capacitance values of the first capacitor from the current pulse shapes of the plurality of current pulses and determining whether the capacitance values of the first capacitor increase over time, and wherein the method comprises using increase in the capacitance value of the first capacitance with time as an indication of possible human contact at the detection surface.

9. The method according to claim 1, wherein the impedance bridge comprises a resistor-capacitor second RC bridge comprising a parallel connection of a second resistor (R₂) having a second resistance value and a second capacitor (C₂) having a second capacitance value, and the internal resistor R₀ interconnects the first RC bridge and the second RC bridge.

10. The method according to claim 1, wherein the method comprises determining whether there is possible living body contact at the electrical conductive surface with reference to change in peak currents and/or steady state currents and/or pulse shapes over time or over the plurality of voltage pulses.

11. The method according to claim 1, wherein the voltage pulse is to transition from the first voltage level to the second voltage level in a transition time which is shorter than the characteristic rise-time of the impedance bridge and/or the circuit rise-time of the first RC parallel connection, such that the current response includes a peak current which is characteristic of the internal resistor (R₀).

12. The method according to claim 1, wherein the voltage pulse is to transition from the first voltage level to the second voltage level in a transition time which is 2 μs or less, including 1.5 μs or less, 1.0 μs or less, 0.9 μs or less, 0.8 μs or less, 0.7 μs or less, 0.6 μs or less, 0.5 μs or less, 0.4 μs or less, 0.3 μs or less, 0.2 μs or less, or any range or ranges formed by combination of the aforesaid values.

13. An apparatus for detecting possible living body contact at a contact surface which is an electrically conductive surface, wherein the apparatus comprises a controller, a probing circuit comprising a probing signal generator, a detection circuit, and a data storage device, and wherein the controller is to execute stored instructions to:
Operate the probing circuit to generate a train of probing signals to the contact surface, wherein the train of probing signals comprises a plurality of probing pulses and each probing pulse has a probing voltage and a probing-pulse duration;
Operate the detection circuit to detect current responses and collect current response parameters from the contact surface, the current response parameters being current parameters responsive to the plurality of probing pulses; and
To determining whether there is living body contact at the contact surface with reference to change or changes in the current response parameters collected in response to the plurality of probing pulses.

14. The apparatus according to claim 13, wherein the probing pulses are voltage pulses, and the controller is to operate the probing signal generator to generate probing pulses such that the current responses from a living body in bare-skin contact with the contact surface in response to the probing pulse is a current pulse having responsive current pulse characteristics of a living body; and wherein the responsive current pulse characteristics include a spike and a slow falling curve immediately following the spike, wherein the falling curve falls gradually from an initial value to an asymptotic or steady-state value; and wherein the controller is to operate to determine whether the detected current responses in response to a single probing pulse have the responsive current pulse characteristics of a living body, and to generate an alert signal if the detected current responses have the responsive current pulse characteristics.

15. The apparatus according to claim 14, wherein the current pulse is a responsive current pulse having a spike, a spike peak and a spike-peak value, and wherein the spike-peak value is dependent on physical touching conditions of the living body with the contact surface at an instant when the current response parameters are collected from the contact surface; and wherein the controller is to operate to collect a plurality of responsive current pulses corresponding to a plurality of different physical touching conditions.

16. The apparatus according to claim 15, wherein the controller is to operate to determine whether a collected responsive current pulse comprises the responsive current pulse characteristics, and to proceed to determine whether there is living body contact at the contact surface if the responsive current pulse comprises the responsive current pulse characteristics.

17. The apparatus according to claim 15, wherein the controller is to operating to determine whether changes in the responsive current pulse characteristics are consistent with changes in the physical touching conditions of a living body touch, and to generate an alert signal if the changes in the responsive current pulse characteristics are consistent with the changes in the physical touching conditions of a living body.

18. The apparatus according to claim 13, wherein the controller is to operate to generate a plurality of probing pulses within a detection window and collecting current response parameters in response to the plurality of probing pulses, and wherein the detection window comprises a time duration during which physical touching conditions of the living body on the contact surface are changing.

19. The apparatus according to claim 13, wherein the controller is to operate the probing circuit to generate the probing pulses such that the probing pulse has a probing-pulse duration, a probing-pulse repetition frequency, and a probing voltage amplitude such that the train of probing signals is non-harmful to a living body.

20. The apparatus according to claim 13, wherein the detection circuit comprises a plurality of data acquisition circuits, wherein the data acquisition circuits are to collect current response parameters at a plurality of data collection times, and wherein the data collection times are distributed at different times of current responses in response to a probing pulse.
